(19) United States
(12) Patent Application Publication
(10) Pub. No.: US 2008/0045042 A1
(43) Pub. Date: Feb. 21, 2008

(54) METHOD FOR CRYSTALIZING AMORPHOUS SILICON LAYER AND MASK THEREFOR

(75) Inventors: Fang-Tsun Chu, Taichung County (TW); Jia-Xing Lin, Taipei County (TW)

Correspondence Address: J C PATENTS, INC., 4 VENTURE, SUITE 250, IRVINE, CA, 92618, US

(73) Assignee: INDUSTRIAL TECHNOLOGY RESEARCH INSTITUTE, Hsinchu (TW)

(21) Appl. No.: 11/750,577

(22) Filed: May 18, 2007

(30) Foreign Application Priority Data
Aug. 18, 2006 (TW) 95130366

(51) Int. Cl. H01L 21/428; G03F 1/00

(52) U.S. Cl. 438/799; 430/5; 257/E21.327

(57) ABSTRACT

A method for crystallizing an amorphous silicon layer is provided. (A) A substrate with an amorphous silicon layer thereon is provided. (B) A mask with a mask pattern is provided. The mask pattern includes a first region pattern and a second region pattern in mirror symmetry. (C) The first region pattern is selected as a first scanning region and the substrate is moved toward a first direction, such that a laser beam passes through the first region pattern to crystallize the amorphous silicon layer along the first direction. (D) The second region pattern is selected as a second scanning region and the substrate is moved toward a second direction, such that the laser beam passes through the second region pattern to crystallize the amorphous silicon layer along the second direction. (E) The steps of (C) and (D) are repeated to convert the whole amorphous silicon layer into a polysilicon layer.

### CROSS-REFERENCE TO RELATED APPLICATION

This application claims the priority benefit of Taiwan application serial no. 95130366, filed Aug. 18, 2006. All disclosure of the Taiwan application is incorporated herein by reference.

### BACKGROUND OF THE INVENTION

1. Field of the Invention

The present invention generally relates to a crystallization method and a mask therefor. More particularly, the present invention relates to a method for crystallizing an amorphous silicon layer and a mask suitable for sequential lateral solidification (SLS) laser crystallization.

2. Description of Related Art

In recently years, in order to meet the requirements of high performance flat panel displays and panel integrated circuits, low temperature polysilicon crystallization methods are developed, wherein excimer laser crystallization is the mainstream of the crystallization methods.

FIG. 1 is a diagram showing an apparatus used for sequential lateral solidification laser crystallization. Please refer to FIG. 1, the apparatus 100 for sequential lateral solidification laser crystallization comprises a laser source (not shown), an optical system 110 and a substrate carrier 120. The apparatus 100 for sequential lateral solidification laser crystallization is modified from an excimer laser crystallization apparatus. That is, the high-precision optical system 110 and the substrate carrier 120 for carrying the substrate 130 and moving within a sub-micro range are added in the original excimer laser system.

In particular, the laser beam 140 passing through the mask 112 can be patterned by the mask design on the mask 112 in the optical system 110, and then irradiates on the amorphous layer (α-Si shown in FIG. 1) on the substrate 130 through the projection lens 114. Therefore, a polysilicon layer (p-Si shown in FIG. 1) with a periodic poly-Si grain distribution can be obtained by the mask design which can control the region of film sequential lateral solidification and the position of grain boundary. Therefore, the grain size and the crystallized film quality of the polysilicon layer, which is made by the SLS laser crystallization method, depend on the mask design on the mask 112.

In addition, in order to resolve the problem of film protrusion generation during SLS laser crystallization and increase the grain size of the polysilicon layer, complex and asymmetric patterns are usually designed on the mask for SLS laser crystallization. The reference of U.S. Pat. No. 6,800,540 provides a mask with asymmetric patterns thereon, as shown in FIG. 2. The transparent patterns 210, 220, 230 are designed on the mask 200 to resolve the problem of film protrusion. Moreover, the reference of U.S. Pat. No. 6,770,545 provides a mask with asymmetric patterns thereon, as shown in FIG. 3. A first transparent region L and a second transparent region M are formed on the mask 300, wherein the first transparent region L has four rectangular-shaped patterns L1, L2, L3, L4 with different size, and the second transparent region M has two rectangular-shaped patterns M1, M2 with different size, so as to increase the grain size of polysilicon.

However, when the mask with asymmetric pattern design is used in SLS laser crystallization, the process time can not be reduced effectively because of the restriction of the asymmetric pattern design with the result that the unidirectional scanning should be performed. In order to resolve the problems of film protrusion and unidirectional scanning, another mask design is provided.

FIG. 4 shows a mask applied to SLS laser crystallization in another prior art. Please refer to FIG. 4, mask patterns 410, 420, 430 and 440 are located on the mask 400. As FIG. 4 shown, the mask patterns 410, 420, 430, 440 are a symmetric pattern design viewing as a whole. Hence, the bi-directional scanning can be performed when using the mask 400. The film protrusion can also be eliminated because of the design of the mask patterns 410, 420, 430 and 440.

However, the mask 400 has four mask patterns 410, 420, 430, 440, and the laser beam (not shown) irradiates on the amorphous layer (not shown) on the substrate (not shown) through the whole mask 400. When moving the substrate (not shown) to perform SLS laser crystallization, only the small distance of the substrate is moved during each substrate movement. Therefore, more extra laser shots are needed in unidirectional scanning of SLS laser crystallization, and the total number of substrate movement is also increased, such that the process time is increased and the process throughput is decreased.

### SUMMARY OF THE INVENTION

The present invention is directed to a method for crystallizing an amorphous silicon layer capable of reducing process time and increasing process performance and throughput.

The present invention is also directed to a mask suitable for SLS laser crystallization, wherein the bi-directional scanning can be performed for laser crystallization so as to reduce the process time and increase the process performance and throughput.

As embodied and broadly described herein, the present invention provides a method for crystallizing an amorphous silicon layer comprising the following steps (A)-(D). First, in the step (A), a substrate with an amorphous layer thereon is provided. Next, in the step (B), a mask with a mask pattern thereon is provided. The mask pattern includes a first region pattern and a second region patter in mirror symmetry. Thereafter, in the step (C), the first region pattern is selected as a first scanning region and the substrate is moved toward a first direction, such that a laser beam passes through the first region pattern to crystallize the amorphous silicon layer along the first direction. Then, in the step (D), the second region pattern is selected as a second scanning region and the substrate is moved toward a second direction opposite to the first direction, such that a laser beam passes through the second region pattern to crystallize the amorphous silicon layer along the second direction. After that, the steps (C) and (D) are repeated to convert the whole amorphous silicon layer into a polysilicon layer.

The present invention also provides a mask suitable for SLS laser crystallization. The mask includes a transparent substrate with a mask pattern thereon. The mask pattern includes a first region pattern and a second region patter in mirror symmetry. When a laser beam irradiates on the mask to form a scanning region, the area of scanning region is smaller than that of the mask pattern.

In the present invention, the area of the mask pattern is larger than that of the scanning region of the laser beam. When the laser crystallization process is performed along the first direction, only a partial region on the mask (the first region pattern) is selected. When the laser crystallization process is performed along the second direction, the other region on the mask (the second region pattern) is then selected. Therefore, the bi-directional scanning can be performed in the method for crystallizing an amorphous layer of the present invention, such that the number of laser shot and the number of substrate movement can be reduced, and the process performance and throughput can be improved.

Reference will now be made in detail to the present preferred embodiments of the invention, examples of which are illustrated in the accompanying drawings. Wherever possible, the same reference numbers are used in the drawings and the description to refer to the same or like parts.

### BRIEF DESCRIPTION OF THE DRAWINGS

FIG. 1 is a diagram showing an apparatus for sequential lateral solidification laser crystallization.

FIG. 2 shows a mask with asymmetric patterns disclosed in U.S. Pat. No. 6,800,540.

FIG. 3 shows a mask with asymmetric patterns disclosed in U.S. Pat. No. 6,770,545.

FIG. 4 shows a mask applied to SLS laser crystallization in the prior art.

FIG. 5 is a diagram showing an apparatus for sequential lateral solidification laser crystallization.

FIG. 6 schematically shows a top view of the mask of FIG. 5.

FIGS. 7A˜7C are diagrams showing the process steps of crystallizing an amorphous layer according to a preferred embodiment of the present invention.

FIG. 8 is a flow chart showing the method for crystallizing an amorphous layer according to a preferred embodiment of the present invention.

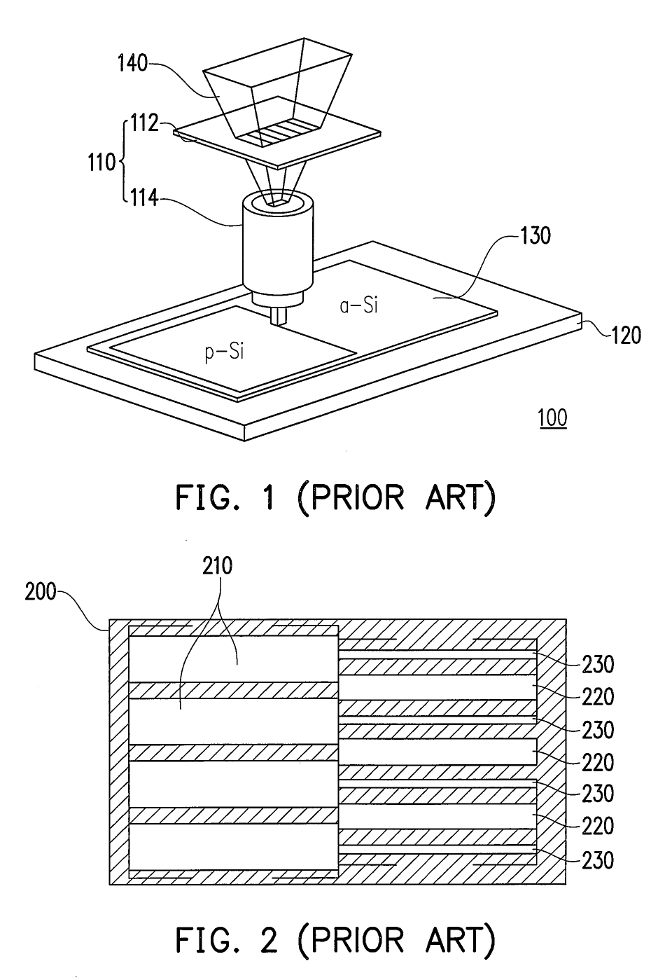

### DESCRIPTION OF EMBODIMENTS

In order to solve the problems of unidirectional scanning being performed and the long process time when using the conventional mask, the present invention provides a mask using bi-directional scanning in a laser crystallization process so as to reduce the process time. The following illustrations are just some of the preferred embodiments of the present invention and should not be used to limit the scope of the present invention.

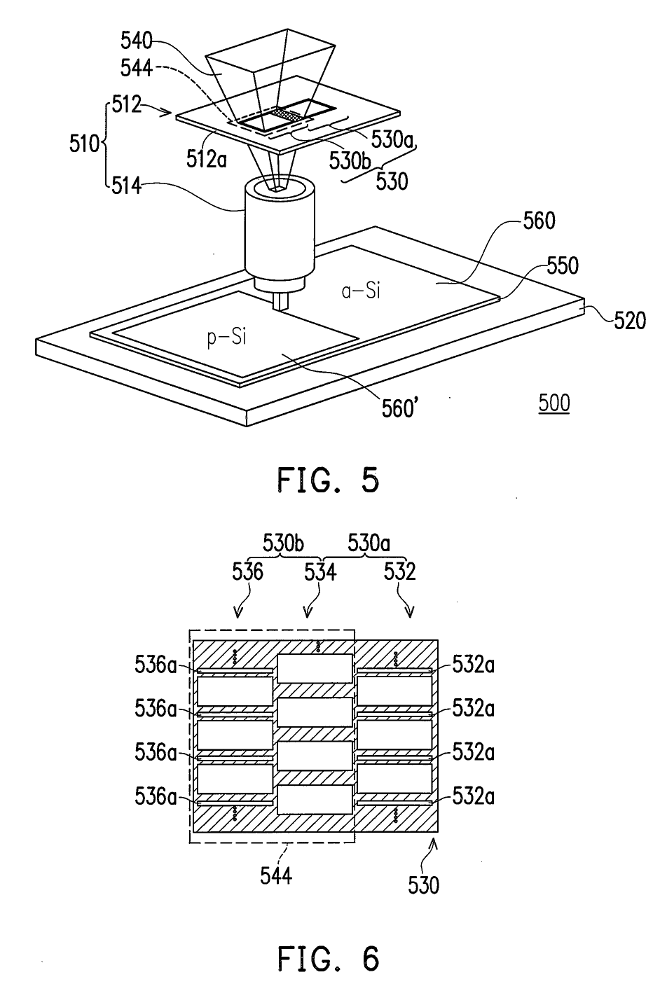

FIG. 5 is a diagram showing an apparatus used for sequential lateral solidification laser crystallization. Please refer to FIG. 5, the apparatus 500 used for sequential lateral solidification laser crystallization comprises a laser source (not shown), an optical system 510 and a substrate carrier 520. The optical system 510 includes a mask 512 and a projector lens 514.

In particular, the mask 512 is suitable for SLS laser crystallization. The mask 512 includes a transparent substrate 512a with a mask pattern 530 thereon. The mask pattern 530 includes a first region pattern 530a and a second region pattern 530b in mirror symmetry. When a laser beam 540 irradiates on the mask 512 to form a scanning region 544, the area of scanning region 544 is smaller than that of the mask pattern 530.

It should be noted that, according to an embodiment of the present invention, the area of the scanning region 544 is larger than or equal to the area of the first region pattern 530a, and the area of the scanning region 544 is also larger than or equal to the area of the second region pattern 530b. Therefore, the laser beam 540 can be completely patterned when it passes through the first region pattern 530a or the second region pattern 530b, and then irradiates on the amorphous layer 560 on the substrate 550 so as to convert the amorphous layer 560 into a polysilicon layer 560′.

FIG. 6 schematically shows a top view of the mask of FIG. 5. Please refer to FIG. 6, in the embodiment, the mask pattern 530 includes a first sub-pattern 532, a second sub-pattern 534 and a third sub-pattern 536, wherein the second sub-pattern 534 is located between the first sub-pattern 532 and the third sub-pattern 536. The first region pattern 530a is composed of first sub-pattern 532 and the second sub-pattern 534, and the second region pattern 530b is composed of the second sub-pattern 534 and the third sub-pattern 536.

As shown in FIG. 6, the first region pattern 530a and the second region pattern 530b are respectively an asymmetric pattern design, and the first region pattern 530a and the second region pattern 530b are in mirror symmetry. In addition, the mask 530 has a transparent region (blank portion in FIG. 6) and a non-transparent region (shaded portion in FIG. 6). The laser beam 540 would pass through the transparent region and then irradiates on the amorphous layer 560 so as to convert the amorphous layer 560 into the polysilicon layer 560′.

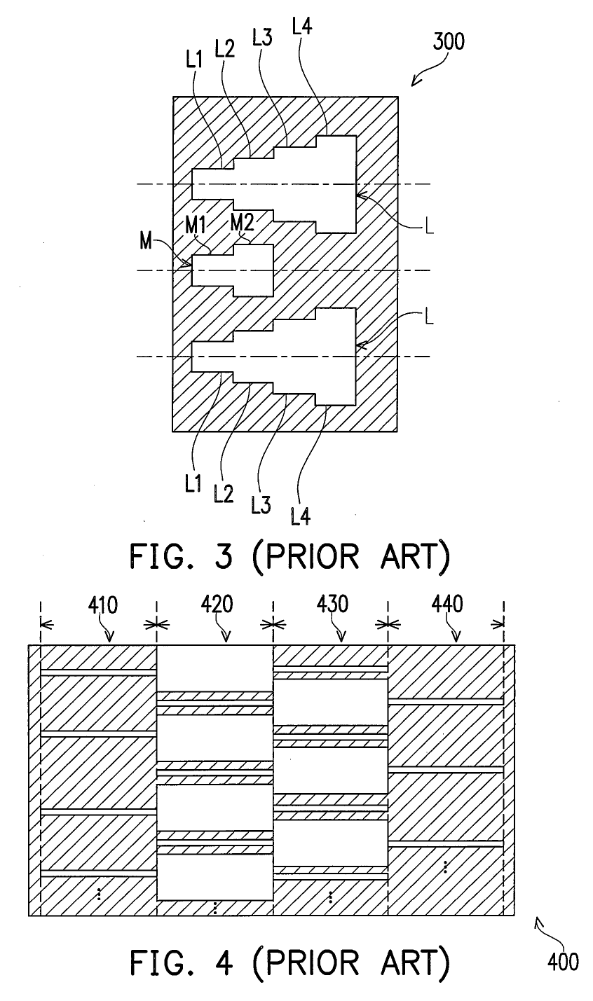

In particular, the design of the mask pattern 530 shown in FIG. 6 is used to eliminate the film protrusion, and thus slits 532a, 536a are respectively formed in the first sub-pattern 532 and the third sub-pattern 536. Also, in other embodiments, the mask pattern 530 can also be designed to increase the grain size of polysilicon (such as the design as shown in FIG. 3) as long as the mask pattern design meet the requirements of that the mask pattern 530 includes the first region pattern 530a and the second region pattern 530b in mirror symmetry, and the area of scanning region 544 formed on the mask 512 from the laser beam 540 is smaller than that of the mask pattern 530. The present invention is not limited by the type the mask pattern design.

In addition, the mask pattern is not limited to include the first sub-pattern 532, the second sub-pattern 534 and the third sub-pattern 536. It can also be designed to have more than three sub-patterns, as long as a portion of the sub-patterns form the first region pattern 530a and the other sub-patterns form the second region pattern 530b, and the first region pattern 530a and the second region pattern 530b are in mirror symmetry. The present invention is not limited the number of sub-patterns of the mask pattern.

In the following paragraphs, the method for crystallizing an amorphous layer using the mask mentioned above is described.

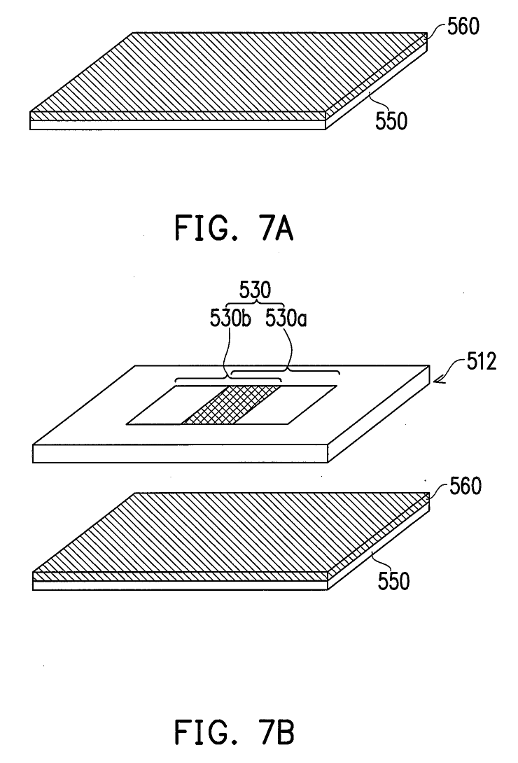

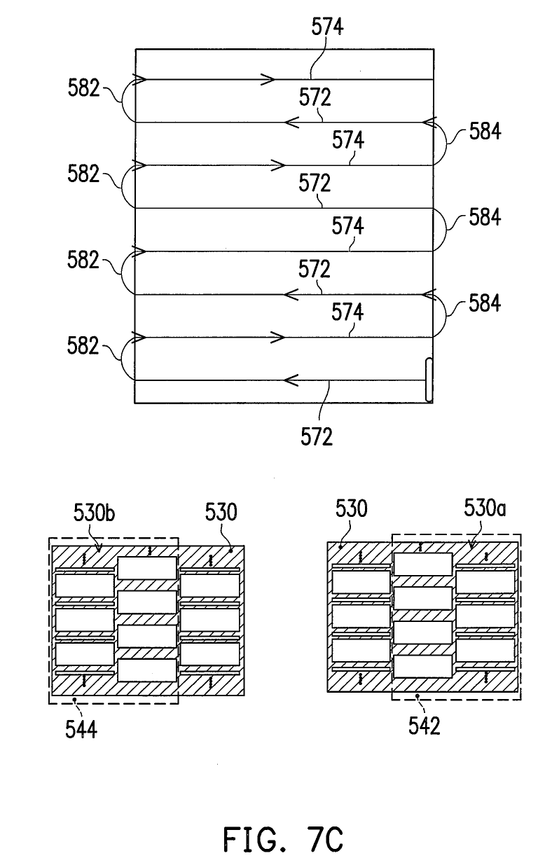

FIGS. 7A-7C show the illustration of process steps for crystallizing an amorphous layer according to a preferred embodiment of the present invention. Please refer to FIGS. 5, 6 and 7A-7C.

First, as shown in FIG. 7A, a substrate 550 with an amorphous silicon layer 560 thereon is provided. The substrate 550 is, for example, a glass substrate, a quartz substrate or other type of substrates. The amorphous silicon layer 560 is formed by, for example, chemical vapor deposition or other methods, which is not limited herein.

Next, please refer to FIG. 7B, a mask 512 with a mask pattern 530 thereon is provided. The mask pattern 530 includes the first region pattern 530a and the second region pattern 530b in mirror symmetry. The mask 530 is, for example, the mask shown in FIG. 6, and thus is not described again.

Thereafter, please refer to FIGS. 5, 6 and 7C, the first region pattern 530a is selected as a first scanning region 542 and the substrate 550 is moved toward a first direction 572, such that the laser beam 540 passes though the first region pattern 530a to crystallize the amorphous silicon layer 560 along the first direction 572. Therefore, a portion of the amorphous silicon layer 560 is crystallized along the first direction 572.

Next, please refer to FIGS. 5, 6 and 7C, the second region pattern 530b is selected as a second scanning region 544 and the substrate 550 is moved toward a second direction 574 which opposite the first direction 572, such that the laser beam 540 passes though the second region pattern 530b to crystallize the amorphous silicon layer 560 along the second direction 574. Therefore, another portion of the amorphous silicon layer 560 is crystallized along the second direction 574.

After that, please refer to FIGS. 5, 6, 7C, repeating the scanning steps along the first direction 572 and the second direction 574 so as to convert the whole amorphous silicon layer 560 into the polysilicon layer 560′.

It should be noted, according to an embodiment, the area of the first scanning region 542 is larger than or equal to the area of the first region pattern 530a, and the area of the second scanning region 544 is also larger than or equal to the area of the second region pattern 530b, such that the laser beam 540 can be completely patterned through the first region pattern 530a or the second region pattern 530b.

Moreover, because the area of each of the first scanning region 542 and the second scanning region 544 is smaller than that of the mask pattern 530, the first region pattern 530a or the second region pattern 530b can be selected depending on the moving direction of the substrate 550, such that the bi-directional scanning can be achieved. That is, when the scanning step is carried out along the first direction 572, the first region pattern 530a is selected as the first scanning region 542. Similarly, when the scanning step is carried out along the second direction 574, the second region pattern 530b is selected as the second scanning region 544. Therefore, the bi-directional scanning can be performed for crystallizing the amorphous silicon layer of the present invention. Accordingly, the number of moving the substrate 550 and the number of laser shot can be reduced so as to reduce the process time and improve the process throughput.

It should be noted that, please refer to FIGS. 5 and 7C, when switching the moving direction of the substrate 550 from the first direction 572 to the second direction 574, a step of aligning the substrate 550 with the mask 512 and the step of selecting the second region pattern 530b as the second scanning region 544, can be performed at the same time.

In other words, during switching stage 582 as shown in FIG. 7C, the step of aligning the substrate 550 with the mask 512 and the step of selecting the second region pattern 530b, can be performed simultaneously. Therefore, the step of selecting the second region pattern 530b does not increase the process time.

In addition, when switching the moving direction of the substrate 550 from the second direction 574 to the first direction 572, the step of aligning the substrate 550 with the mask 512 and the step of selecting the first region pattern 530a as the first scanning region 542, can be performed at the same time.

Similarly, during switching stage 584 as shown in FIG. 7C, the step of aligning the substrate 550 with the mask 512 and the step of selecting the first region pattern 530a, can be performed simultaneously. Therefore, the step of selecting the first region pattern 530a does not increase the process time.

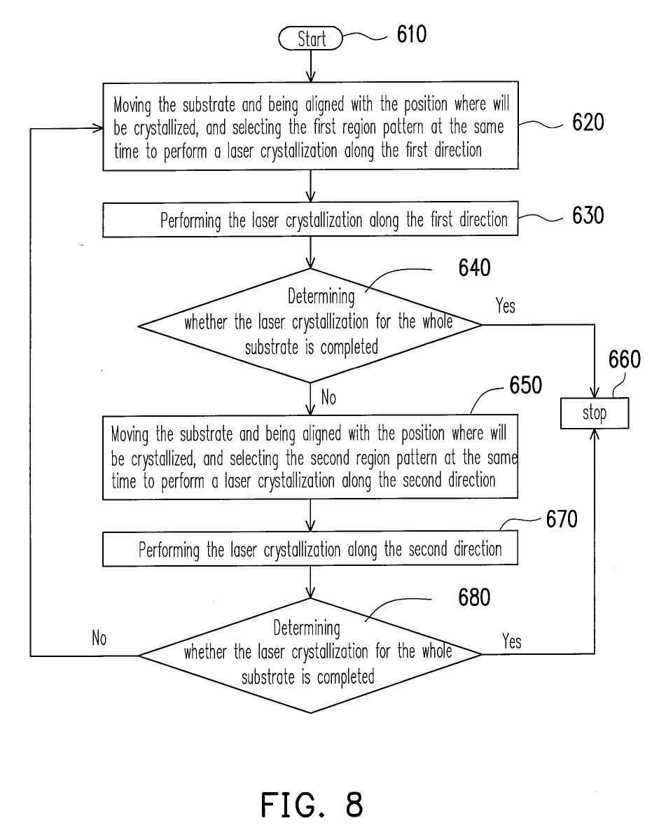

FIG. 8 is a flow chart showing the method for crystallizing an amorphous layer according to a preferred embodiment of the present invention. Please refer to FIGS. 7A-7C and FIG. 8, in the step 610, a crystallization process for the amorphous silicon layer 560 is started. In the step 620, the substrate 550 is moved and aligned with the position where will be crystallized, and the first region pattern 530a is selected at the same time to perform a laser crystallization along the first direction 572. In the step 630, the laser crystallization along the first direction 572 is performed. In the step 640, the step is to determine whether the laser crystallization for the whole substrate is completed or not. If the laser crystallization for the whole substrate is completed, the step 660 is performed to stop the laser crystallization. If the laser crystallization for the whole substrate is not completed, the step 650 is performed.

In the step 650, the substrate 550 is moved and aligned with the position where will be crystallized, and the second region pattern 530b is selected at the same time to perform a laser crystallization along the second direction 574. In the step 670, the laser crystallization along the second direction 574 is performed. In the step 680, the step is to determine whether the laser crystallization for the whole substrate is completed or not. If the laser crystallization for the whole substrate is completed, the step 660 is performed to stop the laser crystallization. If the laser crystallization for the whole substrate is not completed, it should be back to the step 620 to continue the laser crystallization along the first direction 572. The amorphous silicon layer 560 on the substrate 550 can be completely crystallized as the polysilicon layer 560′ through the process flow shown in FIG. 8.

In summary, the method for crystallizing an amorphous silicon layer and the mask therefor in the present invention provides the following advantages.

(1) Because the area of mask pattern is larger than that of the scanning region of the laser beam, only the first region pattern is selected when the laser crystallization process is performed along the first direction, and then the second region pattern is selected when the laser crystallization process is performed along the second direction. Therefore, the bi-directional scanning can be performed in the method for crystallizing an amorphous silicon layer of the present invention, so as to reduce the number of the substrate movement and the number of the laser shots to improve the process performance and throughput.

(2) The operation of selecting the first region pattern or the second region pattern is performed when performing at the time with the step of switching the scanning direction. Hence, the step of operation of selecting the first region pattern or the second region pattern does not increase the process time.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A method for crystallizing an amorphous silicon layer, comprising:
(A) providing a substrate with an amorphous silicon layer thereon;
(B) providing a mask with a mask pattern thereon, wherein the mask pattern comprises a first region pattern and a second region pattern in mirror symmetry;
(C) selecting the first region pattern as a first scanning region on the mask and moving the substrate toward a first direction, such that a laser beam passes through the first region pattern to crystallize the amorphous silicon layer along the first direction;
(D) selecting the second region pattern as a second scanning region on the mask and moving the substrate toward a second direction, such that the laser beam passes through the second region pattern to crystallized the amorphous silicon layer along the second direction;
(E) repeating the steps (C) and (D) to convert the amorphous silicon layer on the substrate into a polysilicon layer.

2. The method of claim 1, wherein the area of first scanning region is larger than or equal to the area of the first region pattern.

3. The method of claim 1, wherein the area of second scanning region is larger than or equal to the area of the second region pattern.

4. The method of claim 1, wherein the area of the first scanning region is smaller than the area of the mask pattern.

5. The method of claim 1, wherein the area of the second scanning region is smaller than the area of the mask pattern.

6. The method of claim 1, wherein when switching the moving direction of the substrate from the first direction to the second direction, a step of aligning the substrate with the mask and the step of selecting the second region pattern as the second scanning region are performed at the same time.

7. The method of claim 1, wherein when switching the moving direction of the substrate from the second direction to the first direction, a step of aligning the substrate with the mask and the step of selecting the first region pattern as the first scanning region are performed at the same time.

8. The method of claim 1, wherein the mask pattern comprises:
a first sub-pattern;
a second sub-pattern;
a third sub-pattern, wherein the second sub-pattern is located between the first sub-pattern and the third sub-pattern;
wherein the first region pattern is composed of the first sub-pattern and the second sub-pattern, and the second region pattern is composed of the second sub-pattern and the third sub-pattern.

9. A mask for sequential lateral solidification (SLS) laser crystallization, comprising:
a transparent substrate with a mask pattern thereon, and the mask pattern comprises a first region pattern and a second region patter in mirror symmetry;
wherein, when a laser beam irradiates on the mask to form a scanning region, the area of the scanning region is smaller than the area of the mask pattern.

10. The mask of claim 9, wherein the area of scanning region is larger than or equal to the area of the first region pattern.

11. The mask of claim 9, wherein the area of scanning region is larger than or equal to the area of second region pattern.

12. The mask of claim 9, wherein the mask pattern comprises:
a first sub-pattern;
a second sub-pattern;
a third sub-pattern, wherein the second sub-pattern is located between the first sub-pattern and the third sub-pattern,
wherein the first region pattern is composed of the first sub-pattern and the second sub-pattern, and the second region pattern is composed of the second sub-pattern and the third sub-pattern.
